(19) United States
(12) Patent Application Publication
(10) Pub. No.: US 2008/0079171 A1
(43) Pub. Date: Apr. 3, 2008

(54) SEMICONDUCTOR DEVICE HAVING AN EPITAXIAL-GROWN CONTACT PLUG

(75) Inventor: Yoshinori TANAKA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 11/864,169

(22) Filed: Sep. 28, 2007

(30) Foreign Application Priority Data
Sep. 29, 2006 (JP) 2006/266272

(51) Int. Cl. H01L 23/52; H01L 21/44

(52) U.S. Cl. 257/774; 438/675; 257/E23.141; 257/E21.476

(57) ABSTRACT

A method for manufacturing a semiconductor device includes the steps of epitaxially growing silicon to form a first contact layer in a first opening exposing therethrough a portion of a silicon substrate; forming a dielectric film having a second opening exposing therethrough the top surface of the first contact layer; and epitaxially growing silicon in the second opening on the surface of the first contact layer to form a second contact layer. The first and second contact layers in combination configure a contact plug.

### BACKGROUND OF THE INVENTION

(a) Field of the Invention

The present invention relates to a semiconductor device and, more particularly, to the structure of an epitaxially grown contact plug formed in the semiconductor device. The present invention also relates to a method for manufacturing such a semiconductor device.

(b) Description of the Related Art

DRAM (dynamic random access memory) devices include an array of memory cells each configuring a storage unit for storing therein a binary data. The memory cell includes a MOSFET (metal-oxide-semiconductor field-effect-transistor) formed in the surface region of a semiconductor substrate and a capacitor connected to the MOSFET, and stores therein data by storing electric charge in the capacitor via the MOSFET. In recent years, the line space and width in the semiconductor device has drastically reduced along with the development of the higher integration and higher performance of the semiconductor device. The reduction in the line space and width reduces the contact area between the silicon substrate and contact plugs, and thus increases the contact resistance therebetween.

Generally, the contact plugs are configured by a polysilicon film doped with impurities, such as a phosphor (P) and arsenic (As). In order to reduce the contact resistance between the silicon substrate and the contact plugs, there is a known technique which increases the concentration of impurities doped in the contact plugs. However, a higher concentration of the impurities in the contact plugs may incur diffusion of the impurities doped in the contact plugs toward the silicon substrate during a later heat treatment, thereby causing a short-channel effect m the resultant MOSFETs.

Patent Publication JP-1998-107219A describes a technique for solving the above problem by growing single-crystal silicon on a silicon substrate to form a contact plug layer by using an epitaxial growth technique. In the semiconductor device 100 described in this publication, as shown in FIG. 14, the contact plug layer 21 is grown on the source regions 19 of the silicon substrate 11 by using an anisotropic growth step and a subsequent isotropic growth step. The epitaxial contact plug layer 21 is connected to overlying interconnections or bottom electrodes of capacitors through via-plugs (not shown) including impurity-doped polysilicon.

In the technique of the above patent publication, the contact plug layer 21 including a single-crystal silicon grown on the silicon substrate 11 reduces the interface resistance between the contact plug layer 21 mid the silicon substrate 11 without incurring diffusion of the impurities in tie overlying polysilicon layer toward the silicon substrate. The isotropic deposition step conducted subsequent to the anisotropic deposition step provides a larger contact area between the contact plug layer 21 and the overlying via-plugs, to thereby reduce the contact resistance therebetween. The present inventor analyzed the technique described in the patent publication and noted a problem described below.

In FIG. 14, the development of smaller line space and width reduces the distance between adjacent device areas isolated by the STI (shallow-trench-isolation) structure 12, and thus reduces the gap 101 between adjacent contact plugs of the contact plug layer 21. This may incur a short-circuit failure between adjacent source regions 19 on the STI structure 12.

### SUMMARY OF THE INVENTION

In view of the above, it is an object of the present invention to provide a method for forming contact plugs on a silicon substrate, which is capable of suppressing the short-circuit failure between adjacent contact plugs and reducing the contact resistance between the contact plugs and the silicon substrate.

It is another object of the present invention to provide a semiconductor device including contact plugs manufactured by the above method.

The present invention provides a method for manufacturing a semiconductor device, including: epitaxially growing silicon on a portion of a silicon substrate exposed trough a first opening to form a fit contact layer; forming a first dielectric film having a second opening expositing therethrough a surface of the first contact layer; and epitaxially growing silicon on tie surface of the first contact layer exposed from the second opening to form a second contact layer.

The present invention also provides a semiconductor device including: a first contact layer epitaxially grown on a portion of a silicon substrate exposed through a first opening; a first dielectric film formed on the first contact layer and having therein a second opening exposing therethrough a surface of the first contact layer; and a second contact layer epitaxially grown on the surface of the first contact layer exposed through the second opening.

The above and other objects, features and advantages of the present invention will be more apparent from the following description, referring to the accompanying drawings

### BRIEF DESCRIPTION OF THE DRAWINGS

FIG. 1 is a top plan view showing the layout of a memory cell array of a semiconductor device according to an embodiment of the present invention.

FIGS. 2A and 23 are sectional views taken along lines A-A and B-B, respectively, in FIG. 1.

FIGS. 3A to 9A and FIGS. 3B to 9B are sectional views corresponding to FIG. 2A and FIG. 2B, respectively, showing consecutive steps of a fabrication process for manufacturing the semiconductor device of FIG. 1.

FIG. 10 is a sectional view corresponding to FIG. 2A, showing the structure of the semiconductor device of FIG. 1 including a capacitor.

FIGS. 11A to 11C are sectional views of FIG. 10, showing consecutive steps of a fabrication process for manufacturing the semiconductor device of FIG. 10.

FIG. 12 is a top plan view showing the layout of the peripheral circuit a in the semiconductor device of FIG. 1.

FIG. 13 is a sectional view taken along line XIII-XIII in FIG. 12.

FIG. 14 is a sectional view of a conventional semiconductor device.

### PREFERRED EMBODIMENT OF THE INVENTION

Now, an exemplary embodiment of the present invention will be described with reference to accompanying drawings, wherein similar constituent elements are designated by similar reference numerals throughout the drawings.

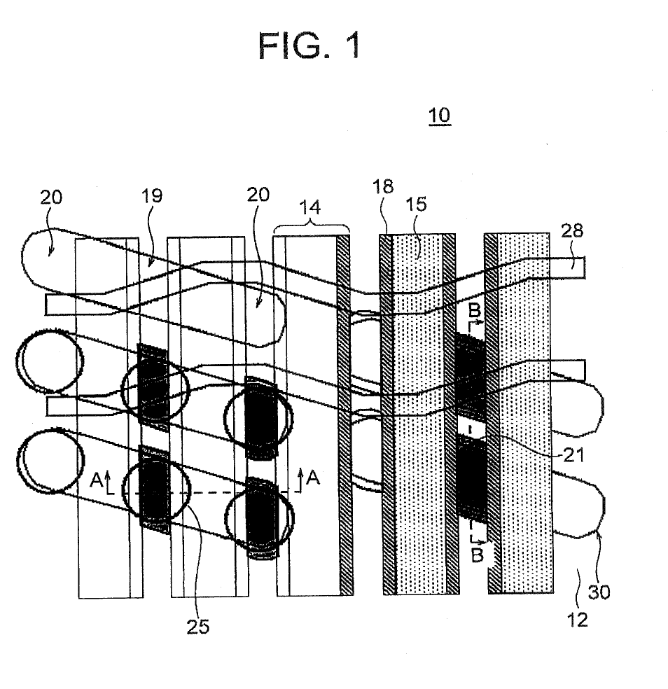

FIG. 1 is a top plan view showing the layout of a memory cell array area of a DRAM device configuring a semiconductor device according to the embodiment of the present invention. The semiconductor device 10 includes a STI structure 12 formed in the surface region of a silicon substrate for isolating the surface region thereof into a plurality of elongate device areas 30, in each of which a pair of MOSFETs are formed. A plurality of word lines, i.e., gate electrodes 15 overlie the silicon substrate while intersecting the device areas 30.

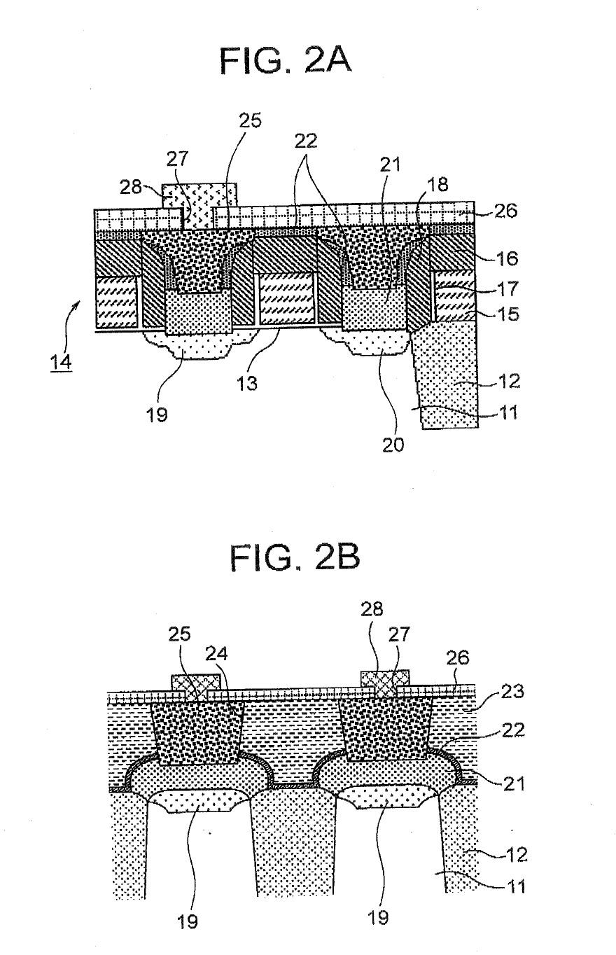

FIGS. 2A and 2B are sectional views taken along lines A-A and B-B, respectively, in FIG. 1. A gate electrode structure 14 includes the gate electrode 15 formed on a gate insulating film 13, an overlying protective film 16 formed on top of the gate electrode 15, sidewall oxide films 17 formed on the side surfaces of the gate electrode 15, and sidewall protective films 18 formed on the side surfaces of the sidewall oxide films 16 and overlying protective film 16. The gate insulating film 13 intervenes between the gate electrode structure 14 and the silicon substrate 11. Some of the gate electrode structures 14 extending on the STI structure 12 include a dummy gate electrode.

The gate electrode 15 has a layer structure including an impurity-doped polysilicon film, a metallic film such as titanium (Ti) or tungsten (W) film, a metal nitride film such as TiN or WN film and a metal silicide film such as TiSi or WSi film. The overlying protective film 16 includes a SiN film and a SiO₂ film whereas the sidewall protective film 18 includes SiN.

Two of the gate electrode structures 14 expose therebetween a potion of the silicon substrate which configures source region 19 or drain region 20. A lightly doped drain (LDD) region (not shown) is disposed outside the source region 19 and drain region 20. The LDD region has a dosage of around 1×10¹² to 1×10¹⁴ atoms/cm². The gate electrode 15 and associated source region 19 and din region 20 configure a MOSFET.

On the portion of the silicon substrate 11 exposed from the gate electrode structures 14, there is provided a first contact layer 21 made of single-crystal silicon grown by an epitaxial growth process. The top of the first contact layer 21 is lower than the top of the gate electrode structure 14.

In FIG. 2B, the first contact layer 21 is grown by an isotropic epitaxial growth technique so that the first contact layer 21 has a larger area in the top portion than in the bottom portion thereof. The first contact layer 21 includes impurities such as phosphor (P) or arsenic (Ar) doped at a dosage of around 1×10¹² to 1×10¹⁴ atoms/cm². On the first contact layer 21, there are consecutively provided a thin contact protective film 22 including SiN, a silicon oxide film and a interlevel dielectric film 23 including impurity-doped silicon oxide doped with impurities such as boron (B) or phosphor (P).

Contact holes 24 penetrate the interlayer dielectric film 23, silicon oxide film and contact protective film 22, and expose therefrom the top of the first contact layer 21. A second contact layer 25 including single-crystal silicon is deposited within the contact holes 24 on the top of the first contact layer 21 by using an epitaxial growth technique. The second contact layer 25 is doped with impurities, such as P or arsenic (As), at a dosage of about 1×10¹³ to 1×10¹⁵ atoms/cm². The first contact layer 21 and second contact layer 25 configure contact plugs for the source/drain regions 19, 20. The interlayer dielectric film 23 and second contact layer 25 have a flush top surface.

On the interlayer dielectric film 23 and second contact layer 25, there is provided an interlayer dielectric film 26 having therein through-holes 27 through which the top of the second contact layer 25 connected to the source regions 19 is exposed. Bit lines 28 are formed within the through-holes 27 and on the interlevel dielectric film 26. The interlayer dielectric film 26 includes SiO₂ or SiN, whereas the bit lines 28 include at least one of Ti, TiN, W, and Al layers

As shown m FIG. 1, a single device area 30 receives therein a pair of MOSFETs sharing a single source region 19. The device areas 30 extend in a direction slightly deviated from the direction normal to the extending direction of the gate electrodes 15. The bit lines 28 extend in a direction substantially normal to the extending direction of the gate electrodes 15, and intersect the device areas 30 at the location overlying the source regions 19.

The first contact layer 21 and second contact layer 25 each have a top surface larger than the bottom surface thereof (FIG. 2B). The bottom of the first contact layer 21 is in contact with a portion of the device region 30 exposed from the gate electrode structures 14, and has a planar shape of an elongate parallelogram extending in the extending direction of the gate electrodes 15. The top surface of the first contact layer 21 is of an elongate parallelogram extending in the extending direction of gate electrodes 15 and narrower compared to the bottom surface of the first contact layer 21. The top surface of the second contact layer 25 has a circular planar shape having a diameter substantially equal to the width of the device areas 30. The bottom of the second contact layer 25 has a planar shape corresponding to the overlapping portion of the top surface of the first contact layer 21 and the top surface of the second contact layer 25.

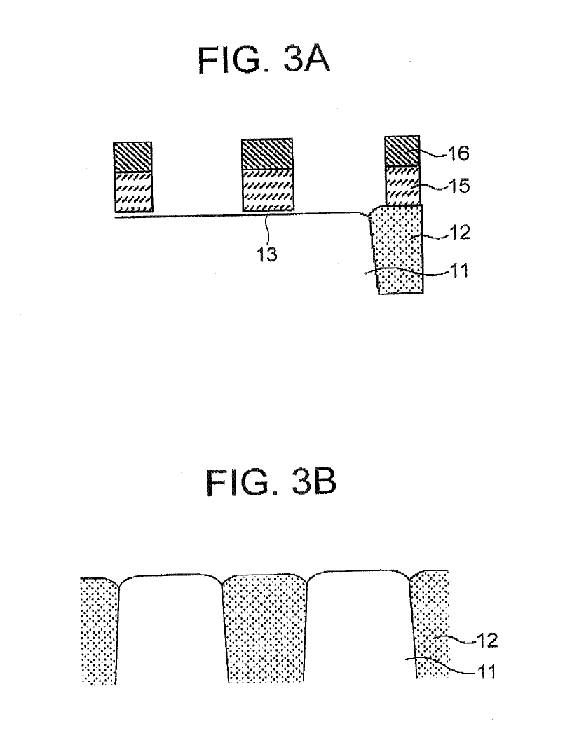

FIGS. 3A to 9A and 3B to 9B are sectional views of the semiconductor device of FIG. 1 during consecutive steps of a fabrication process thereof, taken along lines A-A and a B-B, respectively. The STI structure 12 is first formed in the surface region of the silicon substrate 11 to isolate the device regions from one another, followed by forming the gate insulating film 13 on the device regions of the silicon substrate 11. After depositing a conductive film and an insulating film consecutively on the gate insulating film 13, the conductive film and insulating film are patterned using a dry etching technique. Thus, the gate electrode 15 and overlying protective film 16 are formed, as shown in FIGS. 3A and 3B.

Thereafter, a heat treatment is performed at a substrate temperature of about 750 to 1100 degrees C. for the purpose of removal of damages on the gate insulating film 13, and forming a sidewall oxide film 17 on the side surfaces of the gate electrode 15. The heat treatment may be performed in a chamber while using a lamp anneal unit.

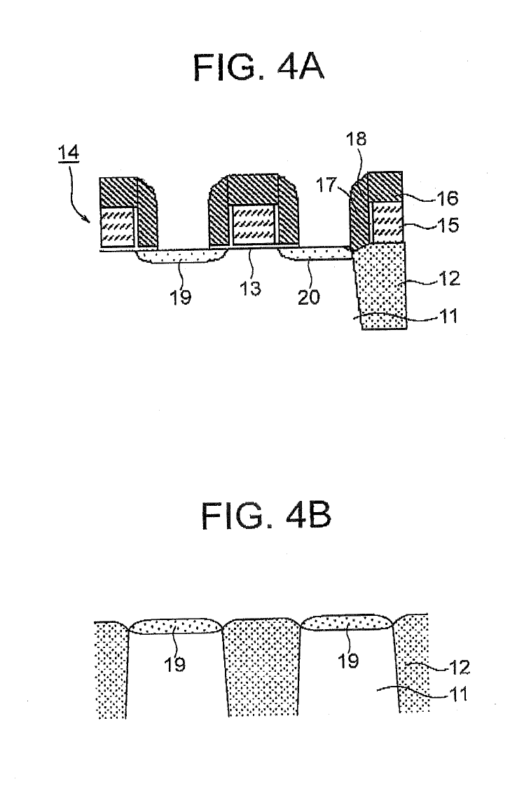

Subsequently, impurities are implanted using an ion-implantation technique at a dosage of about 1×10¹² to 1×10¹⁴ atoms/cm² into the surface region of the silicon substrate 11 exposed from the overlying protective film 16, to thereby form the LDD region of the source region 19 and drain region 20. After forming a thin insulating film on the entire surface, an etch-back process is performed to leave the sidewall protective film 18 on the side surfaces of the overlying protective film 16 and sidewall oxide film 17, as shown in FIGS. 4A and 4B. The sidewall protective film 18 may be silicon nitride film, silicon oxide film, two-layer film including both, or metal oxide film such as Al₂O₃.

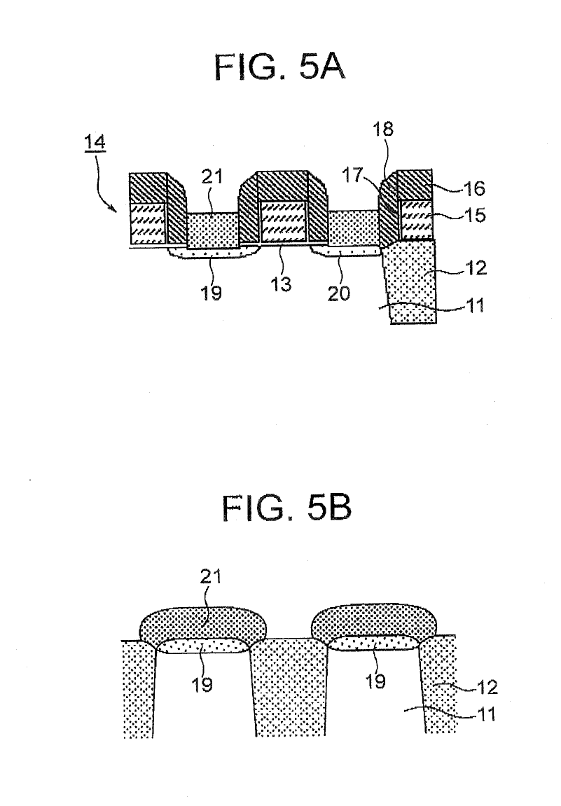

The surface of the silicon substrate 11 is then cleaned using acid solution and alkaline solution, followed by an in-situ heat treatment at a substrate temperature of 700 to 850 degrees C. In an H₂ atmosphere. Thereafter, single-crystal silicon is epitaxially grown at the substrate temperature of 700 to 850 degrees C. to form the first contact layer 21, as shown in FIGS. 5A and 5B. The first contact layer 21 has a thickness smaller than the thickness of the gate electrode structures 14. As understood from FIG. 5B, the single-crystal silicon configuring the first contact layer 21 is grown by an epitaxial step which is isotropic in the extending direction of the gate electrode 15, whereby the first contact layer 21 has a top surface lager than the bottom surface.

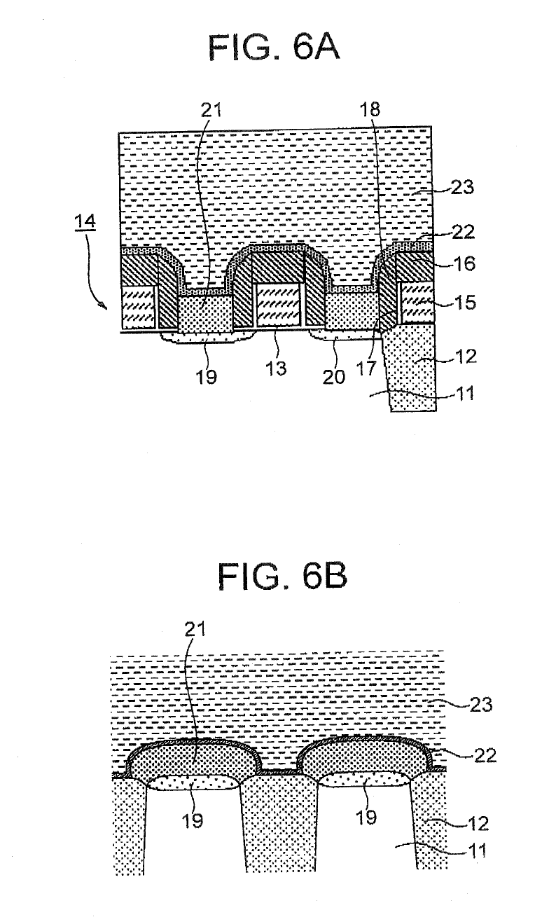

Thereafter, impurities such as phosphor (P) and arsenic (As) are introduced into the first contact layer 21 by using an ion-implantation technique at a dosage of about 1×10¹² to 1×10¹⁴ atoms/cm². A lamp anneal unit is then used to thermally treat the wafer at a substrate temperate of 900 to 1100 degrees C., to diffuse and activate the doped impurities. Thereafter, a CVD technique is used to consecutively deposit the SiN contact protective film 22, silicon oxide film, and interlayer dielectric film 23 including silicon oxide doped with boron (B) and phosphor (P). Subsequently, the interlayer dielectric film 23 is subjected to planarization by using a CMP process as shown in FIGS. 6A and 6B.

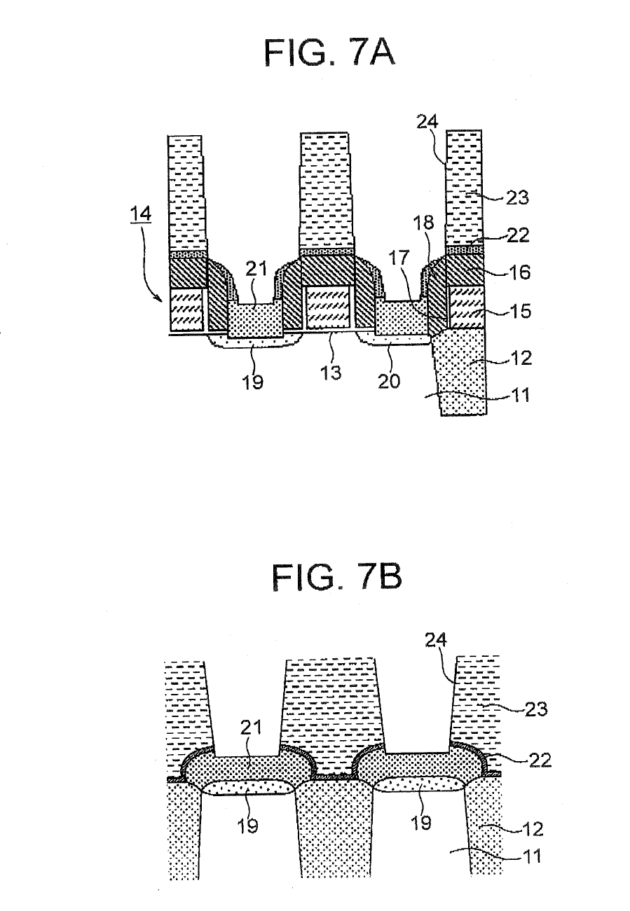

A photolithographic process is then performed to form a mask pattern on the interlevel dielectric film 23, followed by a dry etching process using a RIE (reactive ion etching) technique, to pattern the interlayer dielectric film 23, silicon oxide film and contact protective film 22 for forming contact holes 24 as shown in FIGS. 7A and 7B. The sidewall protective film 18 formed on the side surfaces of the gate electrode structure 14 has a reduced thickness after the dry etching.

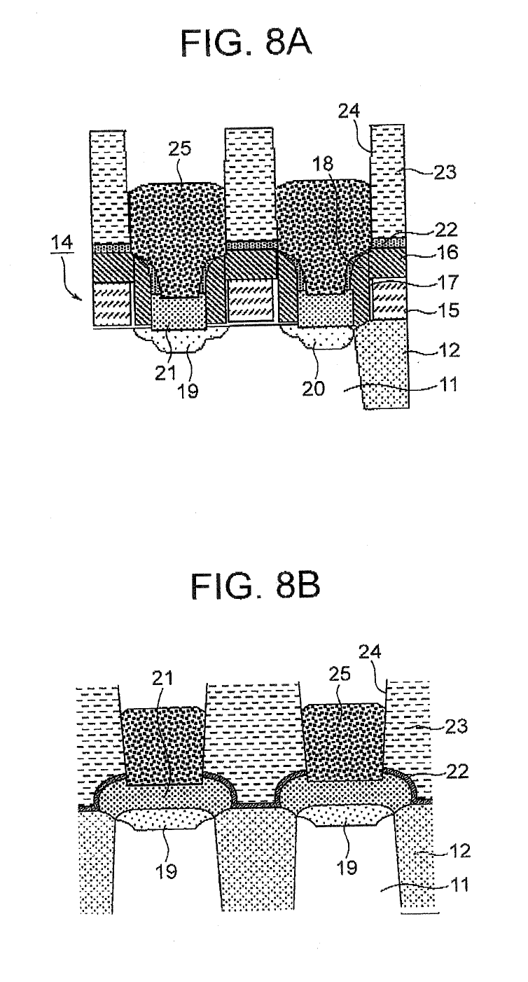

A portion of the first contact layer 21 exposed from the contact holes 24 is then cleaned using acid solution and alkaline solution, followed by generating a H₂ atmosphere for the wafer and subjecting the wafer to an in-situ heat treatment at a substrate temperature of about 700 to 850 degrees C. Thereafter, single-crystal silicon is epitaxially grown to form a second contact layer 25 on the exposed portion of the first contact layer 21 as shown in FIGS. 8A and 8B.

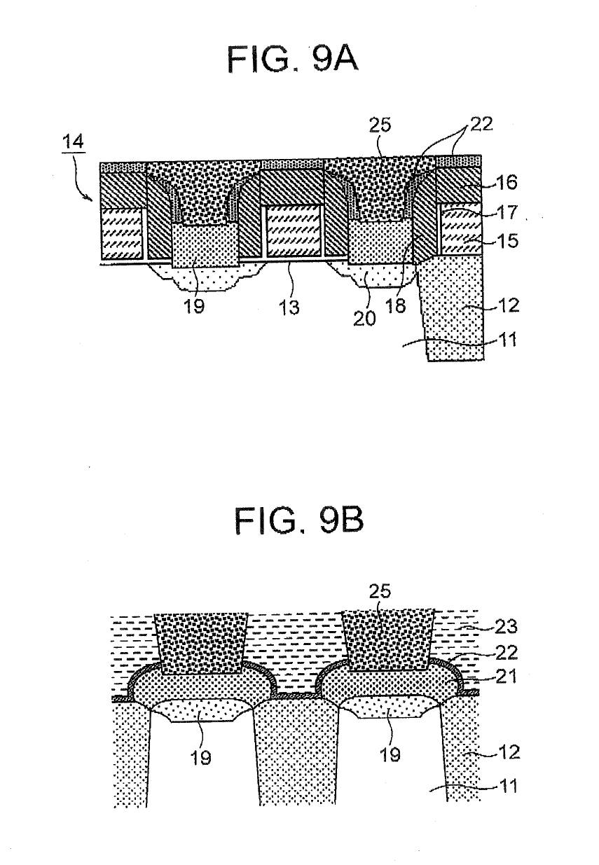

Thereafter, the interlayer dielectric film 23 and second contact layer 25 are polished using a CMP process until the contact protective film 22 formed on the overlying protective film 16 is exposed. Subsequently, the second contact layer 25 is doped with impurities such as P or As at a dosage of 1×10¹³ to 1×10¹⁵ atoms/cm² by using an ion plantation technique. Subsequently, a heat treatment is conducted at a temperature of 900 to 1100 degrees C. on the substrate surface by using a lamp anneal unit, to diffuse and activate the impurities. Thus, the structure of the semiconductor device shown m FIGS. 9A and 9B is obtained.

An interlayer dielectric film 26 is then deposited on the contact protective film 22, interlayer dielectric film 23 and second contact layer 25, and patterned to form therein through-holes 27 which each the top of the second contact layer 25 connected to the source regions 19. After depositing a conductive material on the entire surface including the internal of the, through-holes 27, the conductive material is patterned to form bit lines 28 connected to the second contact layer 25.

The second contact layer 25 including single-crystal silicon grown on the first contact layer 21 by an epitaxial process reduces the interface resistance between the first contact layer 21 and the second contact layer 25, and the first contact layer 21 reduces the contact resistance with respect to the source/drain regions 19, 20. The first contact layer 21 having a smaller thickness prevents the short-circuit failure between adjacent contact plugs configured by the first and second contact layers 21, 25. This provides MOSFETs having higher device characteristics and a higher reliability, while suppressing the short-channel effect therein.

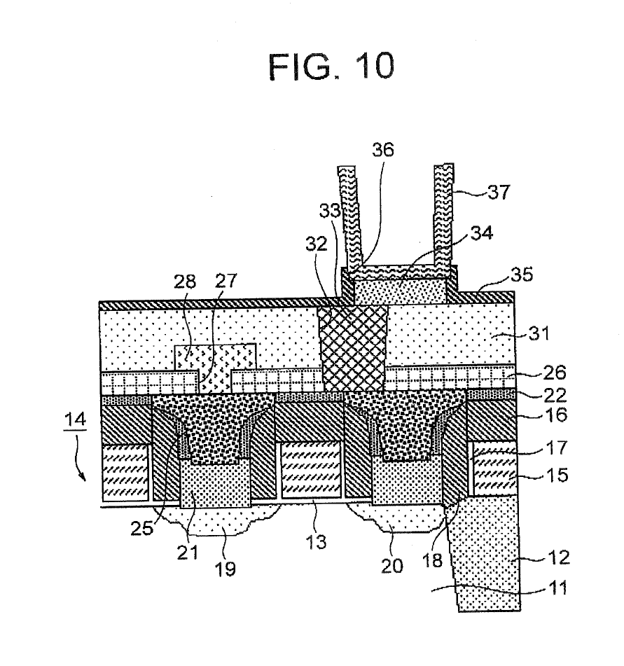

FIG. 10 is a sectional view of the semiconductor device 10 of FIG. 1, showing the structure including the bottom electrode of a cell capacitor. An interlevel dielectric film 31 covers the bit lines 28 on the interlayer dielectric film 26. Through-holes 32 penetrating the interlayer dielectric films 26 and 31 reach the top of the second contact layer 25 connected to the drain regions 20, and receive therein a via-plug 33. The via-plug 33 includes a single or plurality of layers including doped polysilicon, metal such as Ti and W, metal nitride such as TiN and WN, and metal silicide such as TiSi and WSi.

A connection pad 34 including a conductive material same as the conductive material of the via-plug 33 is interposed between the via-plug 33 and the bottom electrode 37 of the cell capacitor. The connection pad 34 is of a substantially circular cylinder having flat top and bottom surfaces. The center of the connection pad 34 is deviated from the center of the via-plug 33. A thin interlayer dielectric film 35 including SiN is formed on the interlayer dielectric film 31 and via-lug 33. The interlevel dielectric film 35 has therein a substantially circular opening for exposing therethrough the connection pad 34, on top of which the bottom electrode 37 is formed.

The cell capacitor is a so-called cylindrical capacitor, wherein the bottom electrode 37 has a bottom portion in contact with the underlying pad 34 exposed from the opening 36 and an upper cylindrical portion extending upward from the periphery of the bottom portion. Although not illustrated, the bottom electrode 37 is associated with a capacitor insulation film and a top electrode consecutively deposited thereon.

The bottom electrode 37 may include a single or a plurality of layers including polysilicon, metal such as W, Ti, Pt and Ru, or nitride of these metals. The capacitor insulation film may include a single or plurality of layers including metal oxide, such as Ta₂O₅, Al₂O₃, HfO and ZrO. The top electrode may include a single or a plurality of layers including metal such as W, Ti, Pt, and Ru, or nitride of these metals.

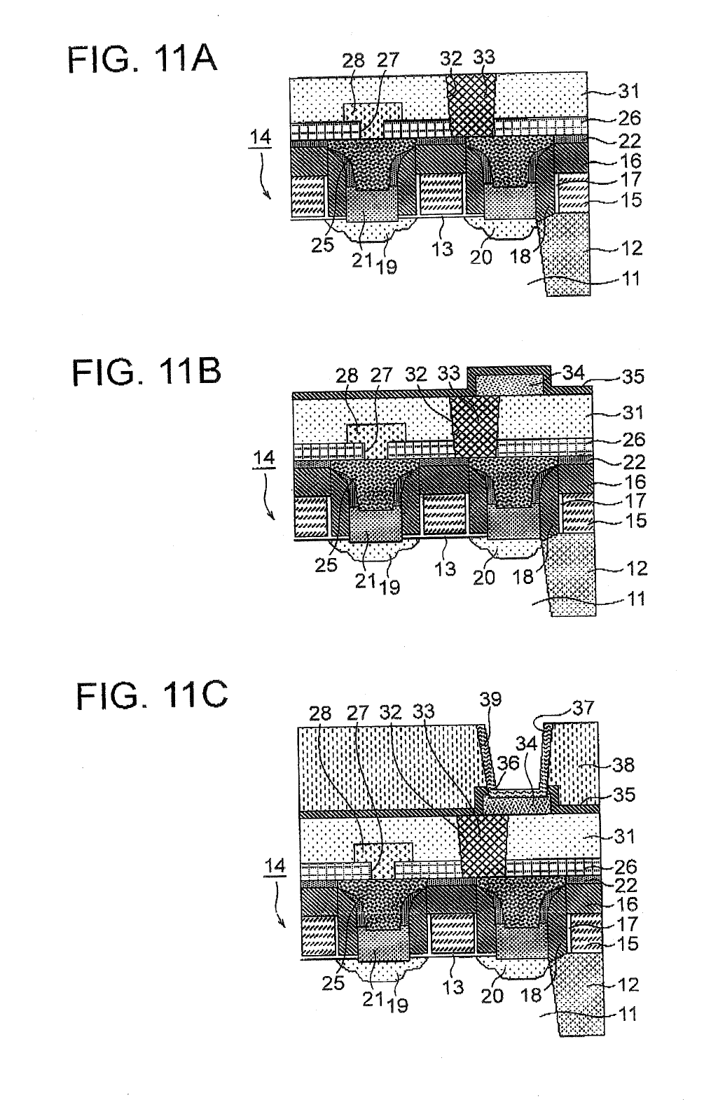

FIGS. 11A to 11C are sectional views of the semiconductor device of FIG. 10, showing consecutive steps of a fabrication process subsequent to the step of forming the interlevel dielectric film 26. After forming the bit lines 28 shown in FIG. 2A, the interlevel dielectric film 31 is deposited to cover the bit lines 28 on the interlevel dielectric film 26. The through-holes 32 are then formed to penetrate the interlevel dielectric films 31, 26 to expose the periphery of top surface of the second contact layer 25. The via-lugs 33 are then formed in the though-holes 32 by depositing a conductive material on the entire surface including the internal of the through-holes 32 and removing a portion of the conductive material on top of the interlevel dielectric film 31, to obtain the structure shown in FIG. 11A.

A thin conductive film is then deposited on the interlayer dielectric film 31 and via-plugs 33, and patterned using a photolithographic technique, to form the connection pads 34 in contact with the via-plugs 33. Thereafter, a thin interlevel dielectric film 35 is formed to cover the connection pads 34 on the interlayer dielectric films 31, to obtain the structure shown in FIG. 11B.

Thereafter, a thick dielectric film 38 including silicon oxide is deposited on the interlayer dielectric film 35, and patterned together with the interlevel dielectric film 35 to form therein cylindrical holes 39 through which the top of connection pads 34 is exposed. The portion of cylindrical holes 39 formed in the interlayer dielectric film 35 constitutes the openings 36. Subsequently, a thin conductive film is deposited on the entire surface including the internal of the cylindrical holes 39, and a portion of the thin conductive films on top of the thick dielectric film 38 is removed to thereby form the bottom electrodes 37, as shown in FIG. 11C. After removing the thick dielectric film 38, a capacitor insulation film and a top electrode film are consecutively deposited on the bottom electrodes 37.

Since the second contact layer 25 allows the contact plugs to have a top surface significantly larger than the bottom surface thereof, the via-plugs 33 may be located, with the center thereof being deviated from the center of the contact plugs configured by the second contact layer 25, without incurring a problem, whereby the flexibility of the layout can be obtained in the semiconductor device.

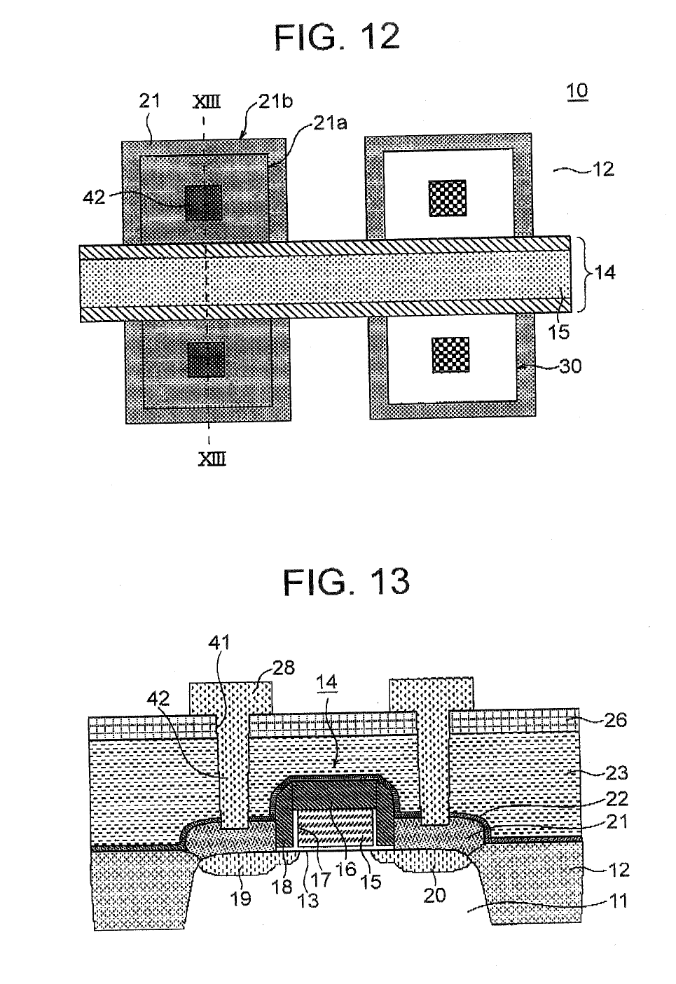

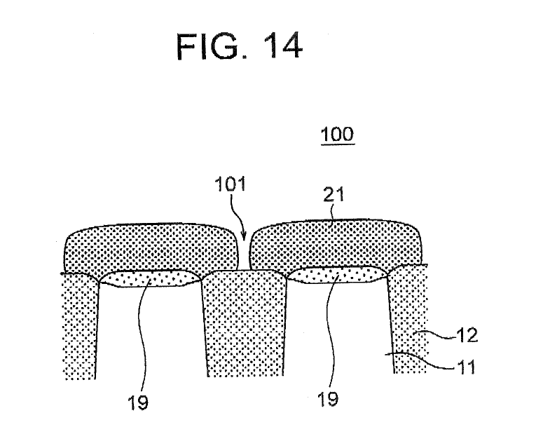

FIG. 12 is a top plan view showing the layout of the peripheral circuit of the semiconductor device 10 of FIG. 1 configuring a DRAM device. The device areas 30 have an elongate rectangular shape extending in the direction normal to the extending direction of the gate electrode structure 14. The first contact layer 21 has a bottom surface 21a in contact with a portion of the device regions 30 exposed from the gate electrode structures 14, whereby the bottom surface 21a is of a substantially rectangular shape.

FIG. 13 is a sectional view taken along line XIII-XIII in FIG. 12. The second contact layer 25 is absent in the peripheral circuit area. The first contact layer 21 is grown by an isotropic epitaxial process, and has a top surface larger than the bottom surface thereof except for the portion in contact with the gate electrode structures 14. Through-holes 41 penetrate the interlevel dielectric films 26, 23, silicon oxide film (not shown) and contact protective film 22 to expose therefrom the top of the first contact layer 21. The bit lines 28 are configured integrally with the via-plugs 42 formed in the through-holes 41.

The method of forming the peripheral circuit area is similar to the method of manufacturing the memory cell array area shown in FIGS. 3A to 9A and 3B to 9B except for the steps as described hereinafter. The step of patterning for forming contact holes 24 in the memory cell array area in FIG. 7 does not form any contact holes in the peripheral circuit area. The step of patterning for forming through-holes 27 receiving therein the bit lines 28 forms through-holes 41 in the interlevel dielectric films 26, 23 and contact protective film 22 in the peripheral circuit area to expose therethrough the top of the first contact layer 41. The step of forming the bit lines 28 includes depositing a metallic material in the through-holes 41 to form via-plugs 42 integrally with the bit lines 28 for connecting together the bit lines 28 and first contact layer 21.

The peripheral circuit area has a larger space between adjacent gate electrodes 15 as compared to the memory cell array area. This allows a larger area to be secured on the top surface of the first contact layer 21 in the peripheral circuit area. Forming via-plugs 42 from a metal having a lower resistivity compared to the second contact layer 25 further reduces the contact resistance for the source/drain regions.

While the invention has been particularly shown and described with reference to the exemplary embodiment and modifications thereof, the invention is not limited to these embodiment and modifications. It will be understood by those of ordinary skill in the art that various changes in form and details may be made therein without departing from the spirit and scope of the present invention as defined in the claims.

What is claimed is:

1. A method for manufacturing a semiconductor device, comprising:
epitaxially growing silicon on a portion of a silicon substrate exposed through a first opening to form a first contact layer,
forming a first dielectric film having a second opening expositing therethrough a surface of said first contact layer; and
epitaxially growing silicon on said surface of said it contact layer exposed from said second opening to form a second contact layer.

2. The method according to claim 1, wherein said first opening is formed between adjacent interconnections each having a side surface covered by an insulating film.

3. The method according to claim 2, wherein said surface of said first contact layer is located within said first opening.

4. The method according to claim 3, further comprising, between said epitaxially growing to form said first contact layer and forming said first dielectric film, depositing a second dielectric film on said first contact layer, and selectively etching said second dielectric film to form a third opening exposing therethrough at least said surface of said first contact layer.

5. The method according to claim 4, wherein said second dielectric film includes silicon nitride.

6. A semiconductor device comprising:
a first contact layer epitaxially grown on a portion of a silicon substrate exposed through a first opening;
a first dielectric film formed on said first contact layer and having therein a second opening exposing therethrough a surface of said first contact layer; and
a second contact layer epitaxially grown on said surface of said first contact layer exposed through said second opening.

7. The semiconductor device according to claim 6, wherein said first opening is formed between adjacent interconnections each having a side surface covered by an insulating film.

8. The semiconductor device according to claim 7, further comprising a second dielectric film deposited between said first contact layer and said second contact layer and having a third opening exposing therethrough at least said surface of said first contact layer.
